(19) United States
(12) Patent Application Publication
(10) Pub. No.: US 2026/0362619 A1
(43) Pub. Date: Nov. 12, 2026

(54) REPLACEABLE INPUT MODULE

(71) Applicant: Microsoft Technology Licensing, LLC, Redmond, WA (US)

(72) Inventors: Bruce James SANDMEYER, Redmond, WA (US); Todd Baker MCCARTHY, Seattle, WA (US); Daniel Calvert CANFIELD, McMinnville, OR (US); Alexander Berton MARINOS, Spokane, WA (US); James David WAHL, Woodinville, WA (US); Kent Allen CAMPBELL, Issaquah, WA (US); Isadora Helena PEREIRA COSTA, Seattle, WA (US)

(73) Assignee: Microsoft Technology Licensing, LLC, Redmond, WA (US)

(21) Appl. No.: 19/203,058

(22) Filed: May 8, 2025

(51) Int. Cl. H05K 5/02; G05G 9/047

(52) U.S. Cl. CPC H05K 5/0256; G05G 9/047; G05G 2009/04703

(57) ABSTRACT

A replaceable input module for an input device comprises a housing comprising a seating protrusion configured to be removably received in a seating aperture in the input device, a fastener retention aperture defined in the housing and configured to receive a fastener, and a locating pin. A control stick extends from the housing and a transducer is located within the housing.

### BACKGROUND

Input devices can utilize one or more input modules to receive user input. In some devices, such input modules can be difficult to replace, occupy significant packaging space, lack durability, and/or provide limited support for future hardware updates.

### SUMMARY

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Furthermore, the claimed subject matter is not limited to implementations that solve any or all disadvantages noted in any part of this disclosure.

In some examples, a replaceable input module for an input device comprises a housing comprising a seating protrusion configured to be removably received in a seating aperture in the input device, a fastener retention aperture defined in the housing and configured to receive a fastener, and a locating pin. A control stick extends from the housing and a transducer is located within the housing.

In some examples, an input device comprises a replaceable input module. The replaceable input module comprises a housing comprising a seating protrusion configured to be removably received in a seating aperture in the input device, a fastener retention aperture defined in the housing and configured to receive a fastener, and a locating pin. A control stick extends from the housing and a transducer is located within the housing.

In some examples, a replaceable input module for an input device comprises a housing comprising a seating protrusion configured to be removably received in a seating aperture defined in the input device, a fastener retention aperture defined in the housing, a captive fastener extending through the fastener retention aperture, and a locating pin positioned substantially opposite to the seating protrusion. A control stick extends from the housing and a transducer is located within the housing.

### BRIEF DESCRIPTION OF THE DRAWINGS

FIG. 1 depicts an example input device in the form of a game controller that includes replaceable input modules according to examples of the present disclosure.

FIG. 2 shows an enlarged partially exploded view of the game controller and replaceable input module of FIG. 1 according to examples of the present disclosure.

FIG. 3 shows a partially exploded view of the game controller and replaceable input module of FIG. 2 according to examples of the present disclosure.

FIG. 4 is a partial sectional view of the input device taken along lines 4-4 of FIG. 2 according to examples of the present disclosure.

FIG. 5 shows a partial side view of a seating protrusion of the replaceable input module taken from lines 5-5 of FIG. 4 according to examples of the present disclosure.

FIG. 6 is a partial sectional view of the input device showing the replaceable input module partially inserted into a seating aperture of the input device of FIG. 1 according to examples of the present disclosure.

FIG. 7 is a bottom perspective view of the replaceable input device of FIG. 3 according to examples of the present disclosure.

FIG. 8 is a top perspective view of the replaceable input device of FIG. 7 according to examples of the present disclosure.

### DETAILED DESCRIPTION

Electronic devices such as various input devices can utilize one or more input modules to receive and communicate user input to a computing device. In some devices, such input modules can be challenging to replace, occupy significant packaging space, lack durability, and/or provide limited support for future hardware updates. In some replaceable input modules that utilize multiple fasteners, such fasteners can result in instability and module rattle, poor datuming function, and corresponding poor user experiences.

Accordingly, and to address one or more of these shortcomings, the present disclosure describes replaceable input modules and input devices comprising replaceable input modules that include a housing comprising a seating protrusion configured to be removably received in a seating aperture defined in the input device. A fastener retention aperture defined in the housing is configured to receive a fastener, and a locating pin is configured to properly position the housing and module within the input device. A control stick extends from the housing and a transducer is located within the housing.

Advantageously and as described in more detail below, by utilizing the disclosed housing configuration and corresponding input device configuration, along with a single fastener to removably retain the input module in the input device, input modules of the present disclosure embody an easily replaceable and compact design that can be securely affixed to the input device in a manner that provides consistent and accurate datuming with the input device, rattle-free operation, and flexibility to utilize a variety of internal sensor technologies for providing positional output.

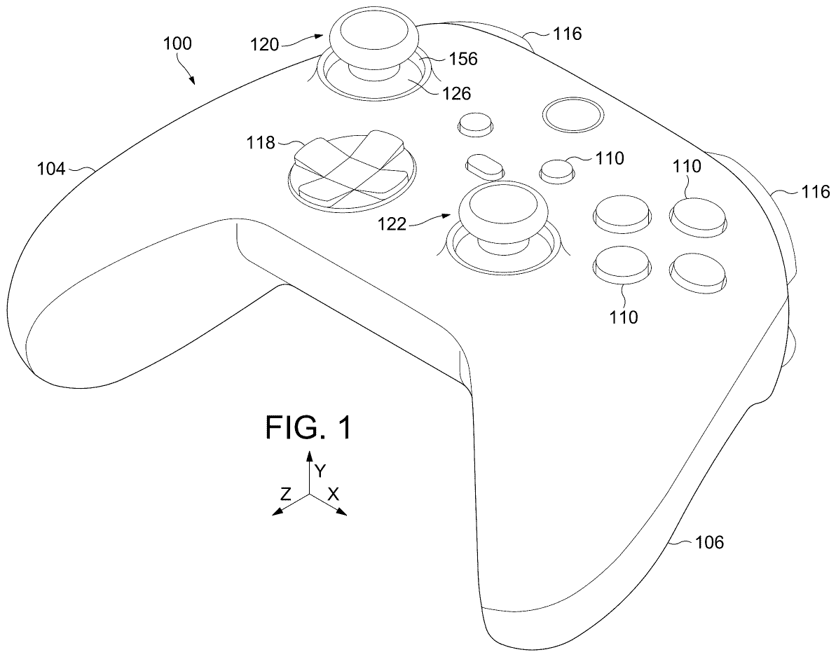

FIG. 1 depicts an example input device in the form of game controller 100. Game controller 100 includes a left handle 104 and right handle 106 configured to be held by a user's left hand and right hand, respectively. In the present example game controller 100 comprises a plurality of input components including buttons 110, bumpers 116, and a direction pad 118. As described in more detail below, and in one potential advantage of the present disclosure, in this example game controller 100 also includes replaceable input modules in the form of left thumbstick module 120 and right thumbstick module 122. As described in more detail below, in this example left thumbstick module 120 and right thumbstick module 122 utilize the same components and are functionally equivalent in structure.

In other examples, input devices of the present disclosure, such as game controller 100, can utilize a single thumbstick and/or different combinations of other input components. In other examples, replaceable input modules of the present disclosure can comprise other analog stick modules, such as joystick modules, and can be utilized with a wide variety of other types and form factors of input devices, including but not limited to keyboards, gamepads, controllers for unmanned vehicles, wearable electronic devices, and laptop devices.

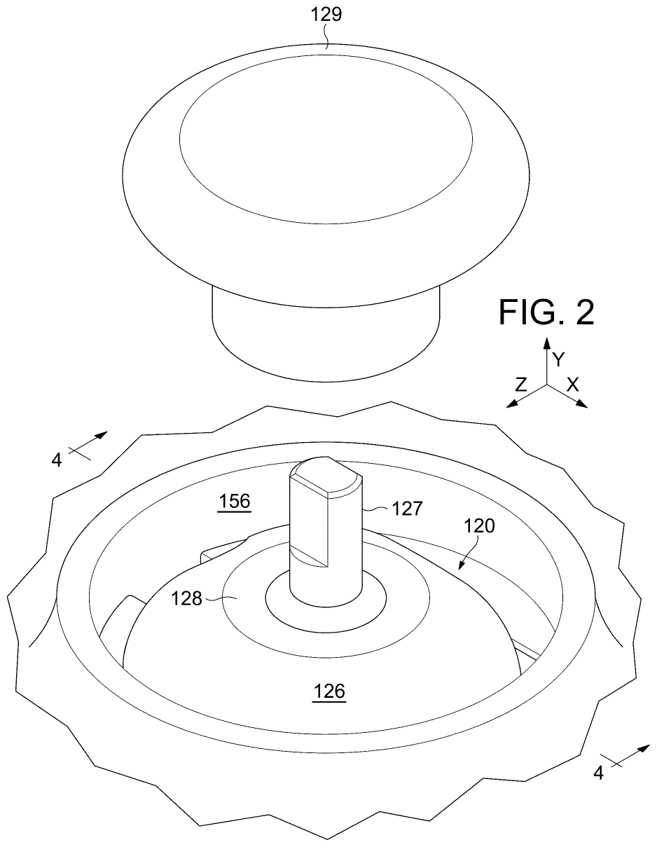

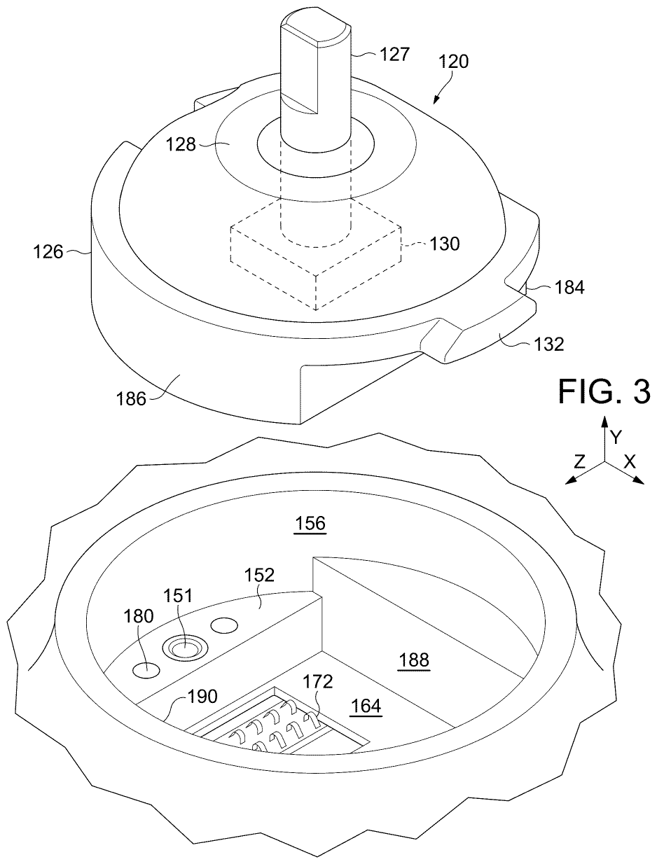

A description of left thumbstick module 120 will now be provided. For purposes of the present disclosure, the components, features, and structures of left thumbstick module 120 and the corresponding features of game controller 100, their interrelationships and operation as described herein, apply equally to the right thumbstick module 122. In one example and with reference also to FIGS. 2 and 3, left thumbstick module 120 includes a housing 126 and a control stick 127 extending from a top surface 128 the housing. FIG. 2 shows a thumbstick cap 129 exploded above control stick 127. Control stick 127 is coupled to a transducer 130 located within the housing 126 and operable to translate movement of the control stick into directional control signals. In different examples transducer 130 can comprise one or more potentiometers, one or more magnetic sensors, and/or any other suitable position transducer technology.

With reference to FIGS. 2-5, housing 126 comprises a seating protrusion 132 configured to be removably received in a seating aperture 134 that is defined in a side wall 136 of game controller 100. In one potential advantage of the present disclosure and as shown in FIG. 5, seating protrusion 132 includes a left angled seating surface 140 and right angled seating surface 142 that contact corresponding left angled controller surface 146 and right angled controller surface 147 of the seating aperture 134. Advantageously and as described further below, these seating and controller surfaces cooperate with other features of left thumbstick module 120 and game controller 100 to prevent movement of housing 126 in the Y-axis or Z-axis directions and securely retain the seating protrusion 132 and left thumbstick module within the game controller.

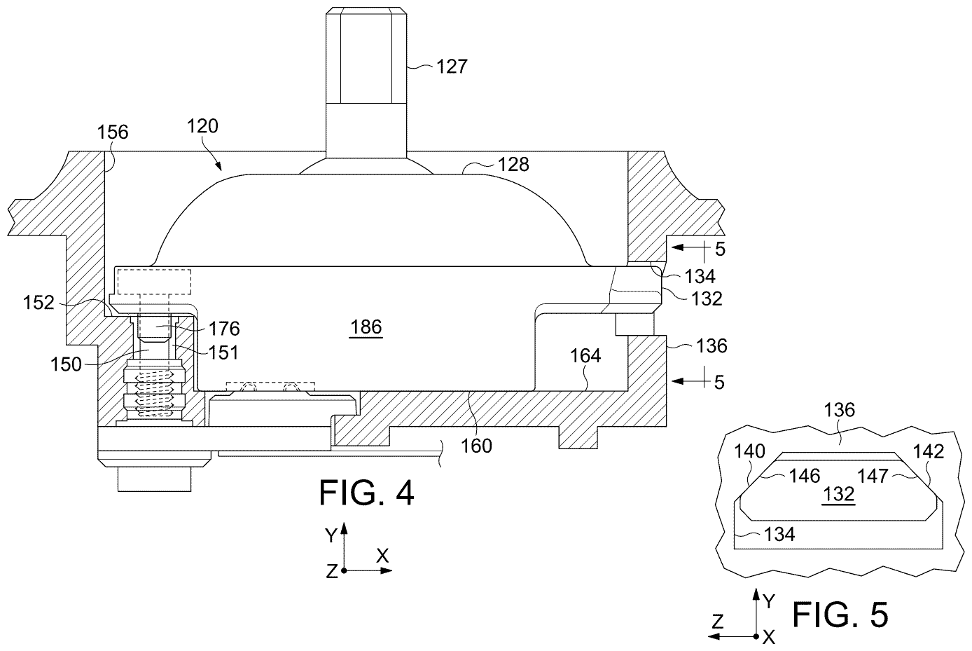

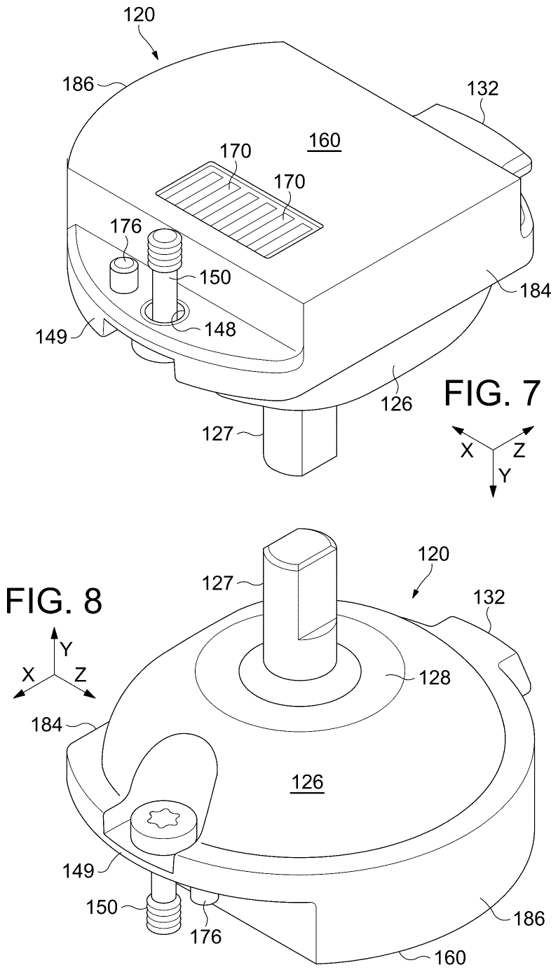

With reference now to FIGS. 7 and 8, a fastener retention aperture 148 is defined in a housing ledge 149 of housing 126 located opposite the seating protrusion 132. With reference also to FIGS. 3 and 4, to removably secure housing 126 and left thumbstick module 120 to game controller 100, a fastener 150 extends through the fastener retention aperture 148 and into a fastener receiving aperture 151 defined in a device ledge 152 located opposite to the seating aperture 134 of the game controller 100. In the present example, fastener 150 is a screw, such as a machine screw, that can be removably received inside a threaded portion of fastener receiving aperture 151, such as a metal threaded insert. Advantageously, by locating fastener retention aperture 148 opposite to the seating protrusion 132 in housing 126 of left thumbstick module 120, and correspondingly locating fastener receiving aperture 151 opposite to seating aperture 134 of game controller 100, the present configuration ensures a secure seating of left thumbstick module 120 into game controller 100 when the fastener is removably affixed within fastener receiving aperture. Additionally, utilizing a machine screw and metal threaded insert provides a more robust removable fastening configuration than, for example, a thread forming screw that is threaded into a plastic substrate.

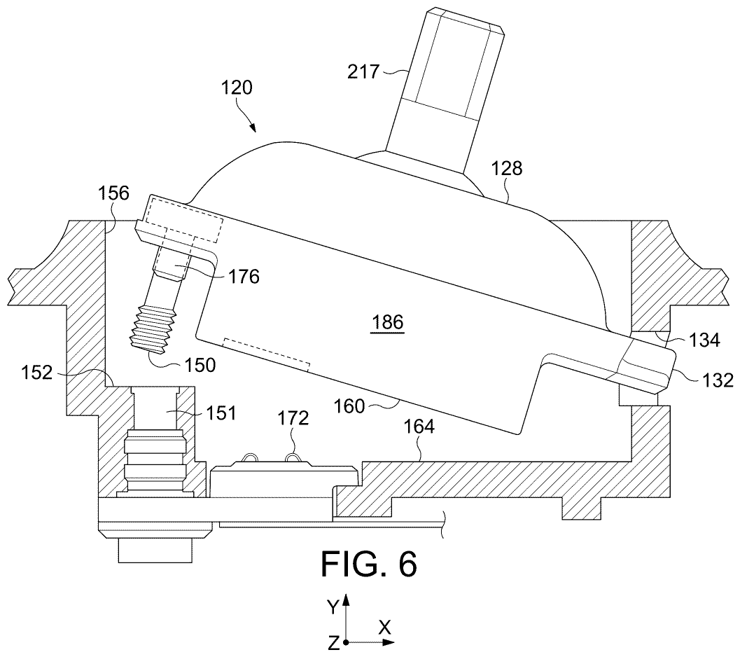

FIG. 6 depicts left thumbstick module 120 partially inserted into module receiving aperture 156 of game controller 100. With reference also to FIG. 4, as fastener 150 is secured into fastener receiving aperture 151, in the present configuration a planar bottom surface 160 of housing 126 that is opposite to top surface 128 of housing is pressed against a planar device seating surface 164 at a bottom of the module receiving aperture 156. With reference also to FIG. 5, as fastener 150 is tightened into fastener receiving aperture 151 and planar bottom surface 160 is biased against planar device seating surface 164, left angled seating surface 140 and right angled seating surface 142 of seating protrusion 132 are urged in the positive Y-direction into contact with left angled controller surface 146 and right angled controller surface 147 of the seating aperture 134. Advantageously, these multiple contacting surfaces cooperate to securely retain left thumbstick module 120 within module receiving aperture 156.

Additionally, with reference to FIG. 7 and in another potential advantage of the present disclosure, replaceable left thumbstick module 120 also comprises a plurality of module electrical contacts 170 located on bottom surface 160 of housing 126. In some examples the plurality of module electrical contacts 170 can be redundant contacts that can improve reliability. With reference also to FIGS. 3 and 6, when left thumbstick module 120 is inserted into module receiving aperture 156 and removably affixed to game controller 100, module electrical contacts 170 contact and are seated against corresponding device electrical contacts 172 located in a recessed portion of device seating surface 164. In this manner, position signals from left thumbstick module 120 can be communicated to game controller 100 and transmitted to a communicatively coupled computing device, such as a gaming console. Additionally, utilizing a plurality of redundant electrical contacts provides enhanced signal reliability as compared to configurations with a single contact.

Additionally and in some examples, left thumbstick module 120 transmits module identification signals via coupled module electrical contacts 170 and device electrical contacts 172 that enable game controller 100 to detect the type of thumbstick module installed, such as particular features and capabilities of the module. Such information can be utilized to adjust software settings of the game controller 100 and/or a communicatively coupled computing device, such as a gaming console.

In the present example, and in another potential advantage of the present disclosure, fastener 150 is a captive screw that is slidably retained within the fastener retention aperture 148. Advantageously, by utilizing a captive fastener within the fastener retention aperture 148, left thumbstick module 120 can be easily shipped and transported, and installed in and/or removed from a game controller while retaining the captive fastener, thereby avoiding inadvertent loss of the fastener and facilitating fast and easy installation of the module in the controller.

As noted above and with reference to FIGS. 3, 4, and 7, housing 126 also comprises a locating pin 176 positioned substantially opposite to seating protrusion 132. Advantageously, when left thumbstick module 120 is inserted into module receiving aperture 156, locating pin 176 is inserted into corresponding locating pin aperture 180 defined in device ledge 152 to properly locate left thumbstick module within game controller 100 and provide additional engagement between left thumbstick module and game controller to securely retain the module within the module receiving aperture.

In the present configuration and with reference to FIGS. 3, 7, and 8, housing 126 comprises a substantially planar side 184 and an arcuate side 186 opposite to the substantially planar side. In this configuration, seating protrusion 132, locating pin 176, fastener retention aperture 148, and fastener 150 are located between the substantially planar side 184 and the arcuate side 186. In one potential advantage of the present disclosure, this configuration communicates a clear visual indication of the proper orientation of the housing 126 for insertion into the module receiving aperture 156. For example and with reference to FIG. 3, substantially planar side 184 visually corresponds to planar wall 188 within module receiving aperture 156, and arcuate side 186 corresponds to an opposing arcuate surface 190 within module receiving aperture. Advantageously and in this manner, this configuration of housing 126 cooperates with the configuration of module receiving aperture 156 to provide an intuitive interface that guides a user to properly orient housing for insertion into the aperture.

Further and with this configuration, it is challenging to improperly align the housing 126 with module receiving aperture 156 and force the housing into the aperture in an incorrect orientation, which advantageously discourages attempts at improperly oriented insertions and potential corresponding damage to left thumbstick module 120 and/or game controller 100.

In another potential advantage of the present disclosure, fastener 150 is the only fastener of left thumbstick module 120 that removably secures left thumbstick module to game controller 100. Advantageously in the present configuration, by utilizing a single fastener 150 along with opposing seating protrusion 132 and its cooperation with seating aperture 134 of game controller 100, the installation process for left thumbstick module 120 is further simplified, and risks of encountering installation instability over the useful life of the module and game controller 100 are reduced, for example as compared to thumbstick modules that require two or more fasteners or are soldered to electrical connectors in an input device. Additionally, by utilizing a single fastener 150 to secure left thumbstick module 120 to game controller 100, additional packaging space within the module is made available, thereby enabling future hardware updates and allowing for a variety of internal sensor arrangements and sensor technologies to be utilized in the small form factor of the module.

The following paragraphs provide additional support for the claims of the subject application. One aspect provides a replaceable input module for an input device, the replaceable input module comprising: a housing comprising: a seating protrusion configured to be removably received in a seating aperture defined in the input device; a fastener retention aperture defined in the housing and configured to receive a fastener; and a locating pin; a control stick extending from the housing; and a transducer within the housing. The replaceable input module may additionally or alternatively include a captive fastener extending through the fastener retention aperture. The replaceable input module may additionally or alternatively include, wherein the captive fastener is the only fastener of the replaceable input module. The replaceable input module may additionally or alternatively include wherein the locating pin is positioned substantially opposite the seating protrusion. The replaceable input module may additionally or alternatively include a plurality of module electrical contacts. The replaceable input module may additionally or alternatively include wherein the plurality of module electrical contacts is located on a bottom surface of the housing that is opposite to a top surface from which the control stick extends. The replaceable input module may additionally or alternatively include wherein the housing comprises a substantially planar side and an arcuate side opposite to the substantially planar side. The replaceable input module may additionally or alternatively include wherein the seating protrusion and the locating pin are located between the substantially planar side and the arcuate side.

Another aspect provides an input device comprising a replaceable input module, the replaceable input module comprising: a housing comprising: a seating protrusion defined in the housing and configured to be removably received in a seating aperture defined in the input device; a fastener retention aperture defined in the housing and configured to receive a fastener; and a locating pin; a control stick extending from the housing; and a transducer within the housing. The replaceable input module may additionally or alternatively include a captive fastener extending through the fastener retention aperture. The replaceable input module may additionally or alternatively include wherein the captive fastener is the only fastener of the replaceable input module. The replaceable input module may additionally or alternatively include wherein the locating pin is positioned substantially opposite the seating protrusion. The replaceable input module may additionally or alternatively include a plurality of module electrical contacts. The replaceable input module may additionally or alternatively include wherein the plurality of module electrical contacts is located on a bottom surface of the housing that is opposite to a top surface from which the control stick extends. The replaceable input module may additionally or alternatively include wherein the housing of the replaceable input module comprises a substantially planar side and an arcuate side opposite to the substantially planar side. The replaceable input module may additionally or alternatively include wherein the seating protrusion and the locating pin are located between the substantially planar side and the arcuate side. The replaceable input module may additionally or alternatively include a device ledge located opposite to the seating aperture, wherein the ledge defines a fastener receiving aperture configured to receive the fastener and a locating pin aperture configured to receive the locating pin.

Another aspect provides a replaceable input module for an input device, the replaceable input module comprising: a housing comprising: a seating protrusion configured to be removably received in a seating aperture defined in the input device; a fastener retention aperture defined in the housing; a captive fastener extending through the fastener retention aperture; and a locating pin positioned substantially opposite to the seating protrusion; a control stick extending from the housing; and a transducer within the housing. The replaceable input module may additionally or alternatively include wherein the captive fastener is the only fastener of the replaceable input module. The replaceable input module may additionally or alternatively include wherein the housing comprises a substantially planar side and an arcuate side opposite to the substantially planar side.

It will be understood that the configurations and/or approaches described herein are exemplary in nature, and that these specific embodiments or examples are not to be considered in a limiting sense, because numerous variations are possible.

The subject matter of the present disclosure includes all novel and non-obvious combinations and sub-combinations of the various processes, systems and configurations, and other features, functions, acts, and/or properties disclosed herein, as well as any and all equivalents thereof.

The claims may refer to “an” element or “a first” element or the equivalent thereof. Such claims should be understood to include incorporation of one or more such elements, neither requiring nor excluding two or more such elements. Other combinations and sub-combinations of the disclosed features, functions, elements, and/or properties may be claimed through amendment of the present claims or through presentation of new claims in this or a related application. Such claims, whether broader, narrower, equal, or different in scope to the original claims, also are regarded as included within the subject matter of the present disclosure. As used herein, the phrase “and/or” means any or all of multiple stated possibilities.

1. A replaceable input module for an input device, the replaceable input module comprising:
a housing comprising:
a seating protrusion configured to be removably received in a seating aperture defined in the input device;
a fastener retention aperture defined in the housing and configured to receive a fastener; and
a locating pin;
a control stick extending from the housing; and
a transducer within the housing.

2. The replaceable input module of claim 1, further comprising a captive fastener extending through the fastener retention aperture.

3. The replaceable input module of claim 2, wherein the captive fastener is the only fastener of the replaceable input module.

4. The replaceable input module of claim 1, wherein the locating pin is positioned substantially opposite the seating protrusion.

5. The replaceable input module of claim 1, further comprising a plurality of module electrical contacts.

6. The replaceable input module of claim 5, wherein the plurality of module electrical contacts is located on a bottom surface of the housing that is opposite to a top surface from which the control stick extends.

7. The replaceable input module of claim 1, wherein the housing comprises a substantially planar side and an arcuate side opposite to the substantially planar side.

8. The replaceable input module of claim 7, wherein the seating protrusion and the locating pin are located between the substantially planar side and the arcuate side.

9. An input device comprising a replaceable input module, the replaceable input module comprising:
a housing comprising:
a seating protrusion defined in the housing and configured to be removably received in a seating aperture defined in the input device;
a fastener retention aperture defined in the housing and configured to receive a fastener; and
a locating pin;
a control stick extending from the housing; and
a transducer within the housing.

10. The input device of claim 9, wherein the replaceable input module further comprises a captive fastener extending through the fastener retention aperture.

11. The input device of claim 10, wherein the captive fastener is the only fastener of the replaceable input module.

12. The input device of claim 9, wherein the locating pin is positioned substantially opposite the seating protrusion.

13. The input device of claim 9, wherein the replaceable input module further comprises a plurality of module electrical contacts.

14. The input device of claim 13, wherein the plurality of module electrical contacts is located on a bottom surface of the housing that is opposite to a top surface from which the control stick extends.

15. The input device of claim 9, wherein the housing of the replaceable input module comprises a substantially planar side and an arcuate side opposite to the substantially planar side.

16. The input device of claim 15, wherein the seating protrusion and the locating pin are located between the substantially planar side and the arcuate side.

17. The input device of claim 9, further comprising a device ledge located opposite to the seating aperture, wherein the ledge defines a fastener receiving aperture configured to receive the fastener and a locating pin aperture configured to receive the locating pin.

18. A replaceable input module for an input device, the replaceable input module comprising:
a housing comprising:
a seating protrusion configured to be removably received in a seating aperture defined in the input device;
a fastener retention aperture defined in the housing;
a captive fastener extending through the fastener retention aperture; and
a locating pin positioned substantially opposite to the seating protrusion;
a control stick extending from the housing; and
a transducer within the housing.

19. The replaceable input module of claim 18, wherein the captive fastener is the only fastener of the replaceable input module.

20. The replaceable input module of claim 18, wherein the housing comprises a substantially planar side and an arcuate side opposite to the substantially planar side.
